(19) United States
(12) Patent Application Publication
(10) Pub. No.: US 2026/0288019 A1
(43) Pub. Date: Sep. 24, 2026

(54) BRIGHT LIGHT SOURCE FOR METROLOGY

(71) Applicant: Nanoverse Technologies Ltd, Beaverton, OR (US)

(72) Inventors: Jeff Albelo, Beaverton, OR (US); William Robertson, Beaverton, OR (US); Garrett Budnik, Beaverton, OR (US); Jared Richter, Beaverton, OR (US)

(73) Assignee: Nanoverse Technologies Ltd, Beaverton, OR (US)

(21) Appl. No.: 19/088,797

(22) Filed: Mar. 24, 2025

(51) Int. Cl. G03F 7/00

(52) U.S. Cl. CPC G03F 7/706849

(57) ABSTRACT

An improved Bright Field-Dark Field three-dimensional metrology system for semiconductor wafers, that encompasses an apparatus and method of providing a bright, white encoded light to a target that provides faster, superior surface defect detection with a higher resolution. It utilizes an illumination light that has its shape altered to closer approximate the shape of the line sensors that receive the reflected and refracted structured light from the illuminated target. The illuminating light is altered such that it is converging in one axis and convergent in the other axis with the angled light enabling better resolution of the defect areas investigated.

### COPYRIGHT STATEMENT

A portion of the disclosure of this patent document contains material that is subject to copyright protection. The copyright owner has no objection to the facsimile reproduction by anyone of the patent document or the patent disclosure as it appears in the Patent and Trademark Office patent file or records, but otherwise reserves all copyright rights whatsoever.

### FIELD

The present disclosure relates, in general, to the creation of a more uniform, brighter, more intense encoded light source for use in the metrology of semiconductor components such as Si wafers using optical critical dimension spectrometry.

### BACKGROUND

While the semiconductor industry continues to produce even smaller devices that are more complex and contain more materials, the practical limits to this micro sizing are determined by the ability to evaluate small details in the semiconductor's structure. To properly evaluate these nanometer-scale features for critical dimension faults requires an ever-increasing level of precision. With current dimensional metrology, one way to increase this level of measurement is with an illuminating source that is as bright as possible, has a uniform illuminating photon density and has an efficient light beam geometry that is configured closely to the sensor shape to illuminate as little outside the scannable area as possible. This will allow for more precise, faster scanning. To accomplish this is a difficult task because there are operational limits as to how much power from laser beam can be input to the system without damaging other components such as the laser phosphor.

Henceforth, an extremely bright white encoded light that has a uniform photon density and a geometric configuration closer to the shape of the sensors, would fulfill a long felt need in the semiconductor metrology industry. This new invention utilizes and combines known and new technologies in a unique and novel configuration to overcome the aforementioned problems and accomplish this.

### BRIEF SUMMARY

In accordance with various embodiments, a method and apparatus are provided to provide extremely bright, white, encoded light to a metrology station.

In one aspect, an optics system to provide a white encoded light that will not damage the laser phosphor and provide as bright a white light as possible.

In another aspect, an optics system to provide an illumination source to an examination target with a more uniform photon density.

In yet another aspect, an optics system to provide an efficient illumination source to an examination target that has an efficient geometric configuration that has an aspect ratio much closer to that of the line sensor than a circular light source.

In yet another aspect, an optics system that encodes the illuminating light to be collimatted in one axis and angled in another axis to allow a better quality of reflected light to reach the sensors.

In yet another aspect, a metrology system that utilizes a bright white encoded light and filters some of the specular light going into the Bright Field sensor to prevent saturation of the bright field sensor when operating at the maximum frame rate of the Dark Field sensor.

Various modifications and additions can be made to the embodiments discussed without departing from the scope of the invention. For example, while the embodiments described above refer to particular features, the scope of this invention also includes embodiments having different combination of features and embodiments that do not include all of the above described features.

### BRIEF DESCRIPTION OF THE DRAWINGS

A further understanding of the nature and advantages of particular embodiments may be realized by reference to the remaining portions of the specification and the drawings, in which like reference numerals are used to refer to similar components.

FIG. 1 is a top view of a conventional white light beam used in metrology;

FIG. 2 is a top view of the conventional white light beam on top of the encoded white light beam and overlaid onto the scanner window;

FIG. 3 is a representative drawing of the metrology system;

FIG. 4 is a representative drawing of the path of the collimated light component exiting the cylindrical lens as seen in the first axis;

FIG. 5 is a representative perspective view of the light beam shape provided to the modulator as seen in perspective in the first axis;

FIG. 6 is a representative drawing of the path of the converging light component exiting the cylindrical lens as seen in the second axis; and

FIG. 7 is a representative drawing of the light beam shape provided to the modulator as seen in perspective in the second axis.

### DETAILED DESCRIPTION OF CERTAIN EMBODIMENTS

Reference will now be made in detail to embodiments of the inventive concept, examples of which are illustrated in the accompanying drawings. The accompanying drawings are not necessarily drawn to scale. The described examples are provided for illustrative purposes and are not intended to limit the scope of the invention.

It will be understood that, although the terms first, second, etc. may be used herein to describe various elements, these elements should not be limited by these terms. These terms are only used to distinguish one element from another. For example, a first attachment could be termed a second attachment, and, similarly, a second attachment could be termed a first attachment, without departing from the scope of the inventive concept.

It will be understood that when an element or layer is referred to as being “on,” “coupled to,” or “connected to” another element or layer, it can be directly on, directly coupled to or directly connected to the other element or layer, or intervening elements or layers may be present. In contrast, when an element is referred to as being “directly on,” “directly coupled to,” or “directly connected to” another element or layer, there are no intervening elements or layers present.

As used in the description of the inventive concept and the appended claims, the singular forms “a,” “an,” and “the” are intended to include the plural forms as well, unless the context clearly indicates otherwise. It will also be understood that the term “and/or” as used herein refers to and encompasses all possible combinations of one or more of the associated listed items.

As used herein, the term “collimated” refers to a light that is collimated in one or both axes.

As used herein, the term “blue light laser” refers to any laser light between the wavelengths of 400 and 500 nm although the preferred specific blue light describe herein is around the 445 nm+/−20 nm wavelength.

The present invention relates to a novel design for an improved BF-DF three-dimensional metrology system that encompasses a novel apparatus and method of providing a bright, white encoded light to a target that provides faster, superior surface defect detection with a higher resolution.

The sensors for these 3-D metrology scanning devices generally utilize linear line sensors for the reception of the specular or reflected light. A 16,000 pixel long and one-pixel wide line sensor would be a common sized sensor for semiconductor examination. (These would represent a line approximately 20 mm long and 0.5 microns high.) Using a round illumination source that is reflected or refracted off a target would be inefficient as it provides less bright light resulting in longer collection times for the light sensors, and a lower resolution.

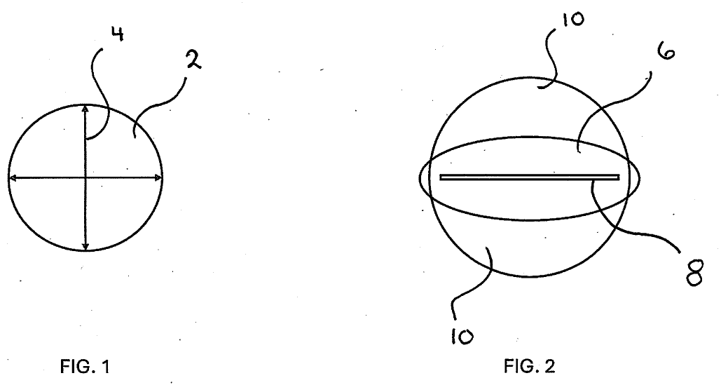

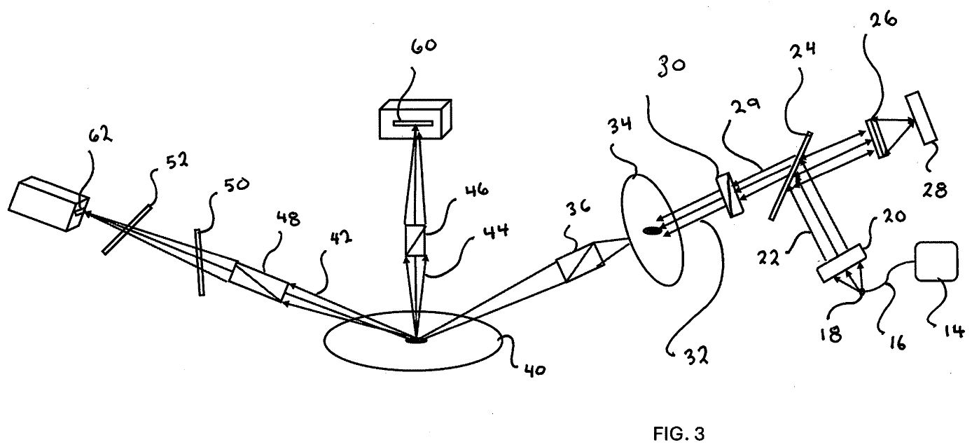

Providing a white encoded light that is as bright as possible, and that has a uniform photon density across its illuminated area, is critical to precise target scanning when looking for 3-D surface irregularities and deformations in Si wafers and semiconductors. Conventional lights used in bright field dark field metrology (BF-DF) scanning provide round illumination sources 2 that have a non-uniform photon density (brightness). One example of this non-uniformity occurs when the center of the light source is the brightest with the photon density decreasing towards the periphery of the light circle as indicated by the arrows 4. (FIG. 1)

Commonly, not all the data captured by the sensors (especially the dark field sensor's data) is useable. Often the edges of the illuminated target area are too poorly illuminated, and their data is not of high enough quality to be trusted or useable. In a 16k pixel line sensor it would be common to chop off the images received on the ends of the line sensor down to a useable 9k pixel array. Because of this, improving the quality of the light source by intensifying the number of photons per unit area and increasing the uniformity of the light would allow a greater area of the target to be satisfactorily illuminated and examined. The more photons that strike the photosites on the line sensor, the stronger the electric signal is that the sensor provides. Brighter light creates more electrical charge, while dimmer light produces less electrical charge. The efficiency of the sensor is governed by the quality of the data which it senses. Thus, quality data is slower for a sensor to obtain with less illumination. With brighter illumination, the frame rates on the sensor cameras can run higher to allow for faster Si wafer examination times. The current standard for BF-DF metrology of a 300 mm Si wafer is 11 wafers per hour.

The most efficient light pattern would be one that covers only what is being examined and only what the sensor can process. This would be an ellipse 6 tailored in length and width to cover an area/shape close to that of the line sensor size 8. Overlaying these geometric shapes, the inefficiency of using the conventional round shape over the elliptical light pattern can be seen with the wasted light in the areas 10 outside of the ellipse 6 but inside the circle. The light from these areas 10 while striking the target and becoming specular or refracted light, do not get sensed as they miss the photosites (pixels) of the line sensors. (FIG. 2)

The overall goal is to provide enough quality specular or refracted light (with the highest density of photons as possible) to the pixels of the speed limiting sensor (generally the dark field sensor) such that this sensor can operate at its fastest capture frame rate or have its frame rate increased while still obtaining a satisfactory resolution.

This is accomplished with two improvements; by tuning the device to generate the maximum intensity light from the Phosphor target and changing the geometric shape of the illumination light to closer resemble the shape and size of the pixel arrangement in the line sensor to maximize the photon density for examination and minimize wasted light. (I.E. that light not reaching the sensors pixels.) The way this was accomplished lead to an unexpected result of additional encoding to the light beam allowing for a higher discrimination of surface defects. Fine tuning these two aspects will increase the efficiency and quality of the examination process.

Looking at FIG. 1, the improved BF-DF metrology unit 12 can best be explained. The laser 14, in the preferred embodiment a 445 nm (blue light) diode laser, produces a laser light that is transmitted through a fiber optic cable 16 to provide a point source 18 of divergent light. The light from the point source 18 passes through a high NA (low f number) aspherical achromatic convex laser collimating lens 20 (placed at least one focal length away from the point source 18) and emerges as a collimated beam of blue light 22 that is directed to a dichroic mirror 24. In the preferred embodiment, this dichronic mirror is customized with thin film coatings on its surface to reflect light in the 490 nm and lower range and transmit the remainder of the light (white light). This reflects the collimated beam 22 toward the aspheric converging lens 26 which converges the light into a circular spot pattern on the laser Phosphor 28.

When this light hits the laser Phosphor, since the laser Phosphor is a Lambertian material it emits divergent white light uniformly in 180 degrees. It is to be noted that the laser Phosphor is sensitive to the amount of energy that is put into it and can burn up if too much power is provided. For this reason, the aspheric converging lens 26/laser Phosphor 28 assembly is tuneable. Although optimally to be placed at one focal length from the laser Phosphor 28, it can be moved closer to, or further from the laser Phosphor 28 adjusting the size and photon density of the spot of light on the laser Phosphor. (Alternatively, the laser Phosphor may be moved with respect to the converging lens.) This is done to maximize the amount of white light generated without damaging the laser Phosphor 28, and while still retaining as much of the light collimation and uniformity as possible.

The aspheric converging lens 26 is selected as it has a high numerical aperture which provides high angle of acceptance of the white light which is sent back through the aspheric lens 26 by the phosphor 28, while maintaining an acceptable level of uniformity in the photon density. This lens 26 collimates the white light 29 which passes through the dichroic mirror 24 and through a cylindrical lens 30. This cylindrical lens 30 only has curvature in one axis and thus focuses light only in one axis. From this lens 30 exits a different shaped light beam, that of a focused line of light rather than a circle. Thus, an elliptical light beam 32 is provided to the modulator wheel 34. This light beam 32 is now smaller and brighter that the original circle since the same number of photons now occupy a smaller area, and the uniformity of photon density has increased slightly. The actual length of the elliptical light beam 32 is sized to coincide approximately with the length of the line sensors 60. (Since the height of a single pixel is in the order of 0.5 microns, this elliptical light beam, although a line light source, will not approximate the aspect ratio of the line sensor, just the length. See FIG. 2.)

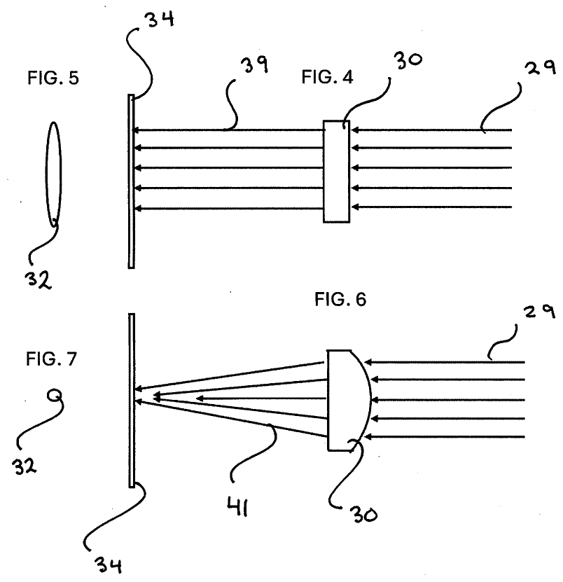

The elliptical light beam 32 that leaves the cylindrical lens 30 is collimated and focused 39 in the one axis as seen from a first axis view (top view in FIG. 4), and convergent 41 in the second axis view (side view in FIG. 5). This results in an elliptical shaped light as seen in perspective in FIGS. 6 and 7 from the top and side views respectively. The cylindrical lens 30 shaped the light beam to an elliptical light source to more closely coincide with the shape of the line sensors 60 and 62. Clearly, the aspect ratio of the line sensors 60 and 62 cannot be maintained because of the diminutive size of a single pixel, so the ellipse much closer approximates the line sensor's length not its height. (See FIG. 2)

The use of this cylindrical lens 30 before the modulator 34 has an unexpected result, as the intent of this lens was to focus, size and shape the light beam close to that of the line sensors 60 and 62 to increase the photon density (brightness), slightly increase the photon uniformity and eliminate wasted light. By using this cylindrical lens 30, the sampling light beam was brighter, more uniform and more efficient. Since the cylindrical lens, focuses the light beam in one axis and converges the light bean the second axis, it added an angle to the light at the image plane, thus when this angled light strikes the target, it will reach areas that the collimated light would not contact and thus will scatter in more directions. This results in an increase in the range of angles that can be seen in BF and DF for different topographies. A richer image is thus presentable to the line sensors.

Explained differently, as compared to conventional BF DF systems where the light after the modulator is fully columnated, here the light is not columnated in the focused axis and the light in that axis has an angular component. If the axis it is focused in (with the angled light) is the same axis as the scanning is taking place in, the light is comes onto the target with a range of angles that are able to illuminate the defect on the surface of the target in more areas so there is a slight increase in the areas of the defect that are illuminated by the structured light and which can scatter the light. This additional amount of scattering allows for higher discrimination of surface defects at the line sensor.

The modulator wheel 34 provides structured light. It receives the elliptical beam from the cylindrical lens 30 and projects a known pattern (often grids or horizontal bars) that deform when striking the target so the sensors (structured light scanners) can calculate defect depth, shape and size as well as other surface information.

Behind the modulator is a 1×relay/imaging lens 36 which images the now structured light with its encoding (modulator lines) from the modulator and images and focuses it on the target (work surface) for examination. This lens focuses a sharp image of the structured light that comes from the modulator 34 onto the target 40. This elliptical light illuminates only the shaped area of what the sensors can see.

The structured, encoded white light that strikes the Si wafer target 40 in the desired area is either reflected (spectral) light 40 or refracted light 44 depending on whether the photons strike a surface irregularity (defect) or just strike a planar face of the Si wafer 40. The refracted light 44 (still in an elliptical shape) is passed through a DF converging magnifying lens 46 placed at a distance from the DF line sensor 60 with a 3× magnification such that the sensor sees one-third less light but spaced across a three times greater area than what the light was at the front of the lens 46. This gives the line sensor 60 greater sensitivity so it can see more detail. The electric signal each pixel sends now represents a smaller area on the target.

There is more spectral light 40 than refracted light 42 coming off the target 38. This spectral light 40 (still in an elliptical shape) is passed through a BF converging magnifying image lens 48 placed at a distance from the BF line sensor 62 with a 5× magnification such that the sensor sees one-fifth less light but spaced across a five times greater area than what the light was at the front of the BF lens 48. This gives the line sensor 62 greater sensitivity so it can see more detail in the same fashion as described above with the DF sensor 60 and its DF converging magnifying lens 46.

The amount of light available to the BF sensor 62 is always much greater than that available to the DF sensor. With more photons reaching the BF image sensor 62, they can be spread out further and still retain the same resolution or detail as the DF sensor although there is a 5×:3× discrepancy in their respective magnifications. These magnification ratios of spectral light to refracted light are operationally set and do not reflect the discrepancy in their ratios of light (which varies but generally exceeds the 5:3 ratio). For this reason, there are a pair of polarizers 50 and 52 that serve to choke off the light going to the BF sensor 62. In cases where the sensors are running at their full speed (commonly 300 kHz) they don't have a lot of dynamic range to change their exposure time so whatever light the sensor sees is what it sees. Since the targets vary, there is no way to know what the ratio of spectral light to refracted light will be and there must be a mechanism to set the amount of light that gets to one sensor relative to the other sensor to get quality data in both channels at the same time. So, using the polarizers 50 and 52, the signal is lowered on the BF to match the fastest frame rate that the DF sensor can operate at with the illumination level of the provided light.

As illustrated, this improved bright field dark field metrology system can run its sensors at a faster frame rate while obtaining better data because the light reaching its line sensors (reflected or refracted) is brighter and has a more uniform photon density. Additionally, because of the angular component introduced into the light before it becomes structured, allows an enhanced examination area of the surface defects. The overall result is an improved surface examination having more precise results and which can be performed at a higher speed.

While certain features and aspects have been described with respect to exemplary embodiments, one skilled in the art will recognize that numerous modifications are possible. Moreover, while the procedures of the methods and processes for building, assembling and using the devices described herein are described in a particular order for ease of description, unless the context dictates otherwise, various procedures may be reordered, added, and/or omitted in accordance with various embodiments.

Consequently, in view of the wide variety of permutations to the embodiments described herein, this detailed description, and accompanying material is intended to be illustrative only, and should not be taken as limiting the scope of the inventive concept. What is claimed as the invention, therefore, is all such modifications as may come within the scope and spirit of the following claims and equivalents thereto.

1. An improved, brighter, elliptical, light source facilitating a faster, more precise semiconductor or Si wafer surface examination from a metrology apparatus, comprising:
a white light source providing a collimated, circular, white light;
a cylindrical lens;
a rotatable modulator wheel;
a one power relay/imaging lens that focuses said light onto said surface;
wherein said collimated, structured white light passes through said cylindrical lens and exits as an elliptically configured light that is focused in one axis and collimated in the other axis, and then passes through said modulator wheel to provide a structured, collimated elliptical light to said relay/imaging lens.

2. The improved brighter, elliptical, light source of claim 1 wherein said white light source further comprises;
a laser light emitter providing a laser light;
an optic cable coupled at an input end to said laser light emitter and providing a divergent laser light point source at an output end;
a collimating lens placed approximately at a distance of at least one focal length from said laser light point source point source;
a dichroic mirror;
a tuneable converging lens/laser phosphor assembly adjustable to maximize an intensity of a white light emitted from said laser phosphor without damaging said laser phosphor; and
wherein said divergent laser light point passes through said collimating lens and a resulting collimated laser point light is partially reflected off a dichroic mirror to said tuneable converging lens/laser phosphor assembly to produce a white light that passes back through said converging lens and said dichroic mirror as a collimated, circular, white light source.

3. The improved brighter, elliptical, light source of claim 1, wherein said structured, collimated elliptical light has a length of 20 mm+/−10 mm and said elliptical light metrology apparatus is an examination apparatus using three-dimensional bright field-dark field metrology.

4. The improved brighter, elliptical, light source of claim 2, wherein said metrology apparatus is an examination apparatus using three-dimensional bright field-dark field metrology.

5. The improved brighter, elliptical, light source of claim 4, wherein said collimating lens is an achromatic, converging collimating lens.

6. The improved brighter, elliptical, light source of claim 4, wherein said said laser light emitter is a diode laser producing a light with a wavelength between 400 and 500 nm.

7. The improved brighter, elliptical, light source of claim 4, wherein said dichroic mirror has a surface coating that reflects light with a wavelength less than 490 nm and transmits light with a wavelength above 490 nm.

8. The improved brighter, elliptical, light source of claim 4, wherein said converging lens is a high aperture, aspheric converging lens.

9. The improved brighter, elliptical, light source of claim 4, wherein said collimating lens is an achromatic, converging collimating lens, and
wherein said laser light emitter is a diode laser producing a light with a wavelength between 400 and 500 nm, and wherein said dichroic mirror has a surface coating that reflects light with a wavelength less than 490 nm and transmits light with a wavelength above 490 nm, and wherein said converging lens is a high aperture, aspheric converging lens.
